(19) United States
(12) Patent Application Publication
(10) Pub. No.: US 2025/0275328 A1
(43) Pub. Date: Aug. 28, 2025

(54) Stretchable Display Device and Method of Fabricating the Same

(71) Applicant: LG Display Co., Ltd., Seoul (KR)

(72) Inventors: Hyo-Kang Lee, Paju-si (KR); Hae-Yoon Jung, Paju-si (KR); Ae-Sun Kim, Paju-si (KR); Myung-Sub Lim, Paju-si (KR); Yu-Ra Jeong, Paju-si (KR); In-Jun Lee, Paju-si (KR)

(21) Appl. No.: 18/786,822

(22) Filed: Jul. 29, 2024

(30) Foreign Application Priority Data
Feb. 26, 2024 (KR) 10-2024-0027389

(51) Int. Cl. H01L 27/15

(52) U.S. Cl. CPC H10H 29/142

(57) ABSTRACT

A display device includes: a substrate; a thin film transistor on the substrate; a first electrode connected to the thin film transistor and a second electrode spaced apart from the first electrode; an adhesive layer between the first and second electrodes; a light emitting diode chip on the adhesive layer and including a junction layer, an anode and a cathode, the anode and the cathode on both sides of the junction layer; and a first connecting layer between the first electrode and the anode and a second connecting layer between the second electrode and the cathode, wherein the anode and the cathode are disposed horizontally.

### CROSS-REFERENCE TO RELATED APPLICATION

The present application claims the priority benefit of Republic of Korea Patent Application No. 10-2024-0027389, filed on Feb. 26, 2024, which is hereby incorporated by reference in its entirety.

### BACKGROUND

### Technical Field

The present disclosure relates to a display device, and more particularly, to a stretchable display device including a vertical light emitting diode chip and method of fabricating the stretchable display device.

### Discussion of the Related Art

Recently, with the advent of an information-oriented society, the interest in information displays for processing and displaying a massive amount of information and the demand for portable information media have increased. As such, a display field has rapidly advanced. Thus, various light and thin flat panel display devices have been developed and highlighted.

With the progress of display-related technology, a flexible display device where a shape is changed by folding, bending or rolling has been researched and developed. Specifically, a stretchable display device where a display element and a conductive line are disposed on a substrate of a flexible material such as plastic has been the subject of a next generation display device. The stretchable display device is stretchable along a predetermined direction to be changed to various shapes.

The stretchable display device includes a rigid part where a pixel is disposed and a soft part where a connection line connecting pixels is disposed. A light emitting diode (LED) chip is mounted on the rigid part.

When a vertical LED chip having a relatively low cost is mounted on the rigid part such that first and second electrodes are disposed at upper and lower portions, respectively, a planarization process for mitigating a step difference of the vertical LED chip has a limitation.

Further, since the first electrode at the lower portion of the vertical LED chip is connected using an anisotropic conductive film (ACF) and the second electrode at the upper portion of the vertical LED chip is connected through the planarization process and a photolithographic process, a fabrication process becomes complicated.

### SUMMARY

Accordingly, the present disclosure is directed to a stretchable display device that substantially obviates one or more of the problems due to limitations and disadvantages of the related art.

An objective of the present disclosure is to provide a stretchable display device where a fabrication process is simplified and an optimization of fabrication is obtained by horizontally disposing and connecting an anode and a cathode of a light emitting diode chip and a method of fabricating the stretchable display device.

Another objective of the present disclosure is to provide a stretchable display device where a thickness is reduced and a fabrication cost is reduced by horizontally disposing an anode and a cathode of a vertical light emitting diode chip and a method of fabricating the stretchable display device.

Additional features and advantages of the disclosure will be set forth in the description which follows, and in part will be apparent from the description, or can be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a substrate; a thin film transistor on the substrate; a first electrode connected to the thin film transistor and a second electrode spaced apart from the first electrode; an adhesive layer between the first and second electrodes; a light emitting diode chip on the adhesive layer and including a junction layer, an anode and a cathode, the anode and the cathode disposed at both sides of the junction layer; and a first connecting layer between the first electrode and the anode and a second connecting layer between the second electrode and the cathode, wherein the anode and the cathode are disposed horizontally.

In another aspect, a method of fabricating a display device includes: forming a thin film transistor on a substrate; forming a first electrode connected to the thin film transistor and a second electrode spaced apart from the first electrode; forming an adhesive layer between the first and second electrodes; forming a first expanding layer exposing the adhesive layer on the first and second electrodes; disposing a light emitting diode chip on the adhesive layer and the first expanding layer, the light emitting diode including a junction layer, an anode and a cathode, the anode and the cathode disposed at both sides of the junction layer; forming a second expanding layer by adding heat to the first expanding layer; and forming a first connecting layer between the first electrode and the anode and a second connecting layer between the second electrode and the cathode, wherein the anode and the cathode are disposed horizontally.

In another aspect, a method of fabricating a display device includes: transferring a light emitting diode chip onto a transfer substrate such that one of an anode and a cathode of the light emitting diode chip contacts the transfer substrate; pushing the light emitting diode chip with a roller; transferring the light emitting diode chip of the transfer substrate onto an adhesive layer of a substrate, the substrate including a thin film transistor, a first electrode connected to the thin film transistor, a second electrode spaced apart from the first electrode and the adhesive layer between the first and second electrodes; and forming a first connecting layer between the first electrode and the anode and a second connecting layer between the second electrode and the cathode, wherein the anode and the cathode are disposed horizontally.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure.

FIG. 1 is a plan view showing a display device according to a first embodiment of the present disclosure.

FIG. 2 is a circuit diagram showing a subpixel of a display device according to a first embodiment of the present disclosure.

FIG. 3 is a plan view showing a rigid part of a display device according to a first embodiment of the present disclosure.

FIG. 4 is a cross-sectional view taken along a line IV-IV of FIG. 3 according to a first embodiment of the present disclosure.

FIGS. 5A to 5D are plan views showing a method of fabricating a display device according to a first embodiment of the present disclosure.

FIGS. 6A to 6D are cross-sectional views showing a method of fabricating a display device according to a first embodiment of the present disclosure.

FIG. 7 is a plan view showing a rigid part of a display device according to a second embodiment of the present disclosure.

FIG. 8 is a cross-sectional view taken along a line VIII-VIII of FIG. 7 according to a first embodiment of the present disclosure.

FIGS. 9A to 9C are plan views showing a method of fabricating a display device according to a second embodiment of the present disclosure.

FIGS. 10A to 10C are cross-sectional views showing a method of fabricating a display device according to a second embodiment of the present disclosure.

FIG. 11 is a plan view showing a rigid part of a display device according to a third embodiment of the present disclosure.

FIG. 12 is a cross-sectional view taken along a line XII-XII of FIG. 11 according to a third embodiment of the present disclosure.

FIGS. 13A to 13D are plan views showing a method of fabricating a display device according to a third embodiment of the present disclosure.

FIGS. 14A to 14D are cross-sectional views showing a method of fabricating a display device according to a third embodiment of the present disclosure.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the present disclosure is only defined by scopes of claims.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

The term “display device” may include a display device in a narrow sense, such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense, such as the LCM, the OLED module and the QD module.

According to circumstances, the LCM, the OLED module and the QD module having a display panel and a driving unit may be expressed as “a display device”, and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of moisture or oxygen into the emitting element layer. In addition, a layer on the array may include an inorganic light emitting layer, for example, a nano-sized material layer or a quantum dot.

The thin film transistor of the present disclosure may include one of an oxide thin film transistor, an amorphous silicon thin film transistor, a low temperature polycrystalline silicon thin film transistor.

Features of various embodiments of the present disclosure may be partially or entirely coupled to or combined with each other. They may be linked and operated technically in various ways as those skilled in the art can sufficiently understand. The embodiments may be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

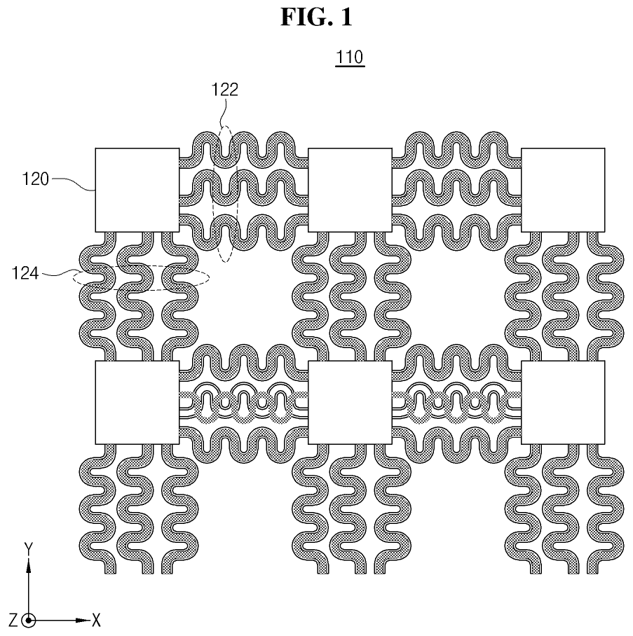

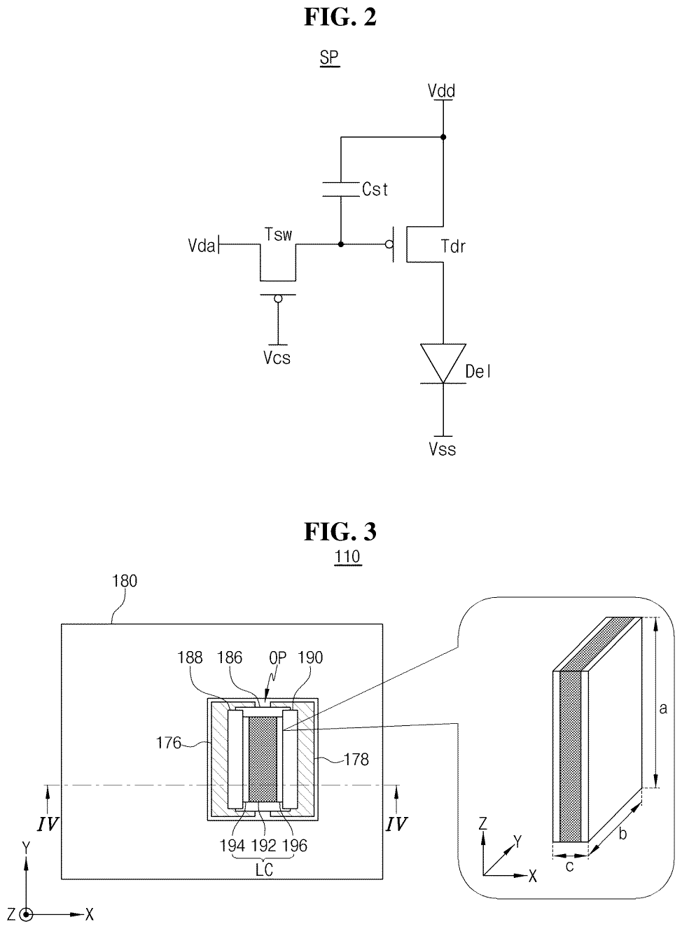

FIG. 1 is a plan view showing a display device according to a first embodiment of the present disclosure, and FIG. 2 is a circuit diagram showing a subpixel of a display device according to a first embodiment of the present disclosure. The display device may be an organic light emitting diode (OLED) display device.

In FIG. 1, a display device 110 according to a first embodiment of the present disclosure includes a plurality of substrates 120, a plurality of horizontal lines 122 disposed between two of the plurality of substrates 120 adjacent to each other along a first direction X and a plurality of vertical lines 124 disposed between two of the plurality of substrates 120 adjacent to each other along a second direction Y crossing the first direction X.

Each of the plurality of substrates 120 includes a plurality of subpixels SP (of FIG. 2) constituting one pixel, and each of the plurality of subpixels SP includes a light emitting diode (LED) Del (of FIG. 2). Each of the plurality of substrates 120 may have a tetragonal shape.

The display device 110 may be stretched along the first direction X and/or the second direction Y. The first direction X and the second direction Y cross each other to constitute a plane of the display device 110.

The plurality of substrates 120 may be spaced apart from each other to have an island shape.

The plurality of horizontal lines 122 and the plurality of vertical lines 124 may have a supporting layer formed of a soft material having bendable and stretchable properties and a conductive layer on the supporting layer and formed of a conductive material.

For example, the plurality of subpixels SP may include red, green and blue subpixels. The plurality of horizontal lines 122 may be a line transmitting a gate voltage, a high level voltage and a low level voltage, and the plurality of vertical lines 124 may be a line transmitting red, green and blue data voltages.

In FIG. 2, the subpixel SP of the display device 110 according to a first embodiment of the present disclosure includes a switching transistor Tsw, a driving transistor Tdr, a storage capacitor Cst and the light emitting diode Del, and each of the switching transistor Tsw and the driving transistor Tdr may have a positive (P) type.

A gate electrode of the switching transistor Tsw is connected to a gate voltage Vsc, a source electrode of the switching transistor Tsw is connected to a data voltage Vda, and a drain electrode of the switching transistor Tsw is connected to a gate electrode of the driving transistor Tdr and a first capacitor electrode of the storage capacitor Cst.

A gate electrode of the driving transistor Tdr is connected to a drain electrode of the switching transistor Tsw and the first capacitor electrode of the storage capacitor Cst, a source electrode of the driving transistor Tdr is connected to a high level voltage Vdd and a second capacitor electrode of the storage capacitor Cst, and a drain electrode of the driving transistor Tdr is connected to a first electrode (anode) of the light emitting diode Del.

The first electrode of the light emitting diode Del is connected to the drain electrode of the driving transistor Tdr, and a second electrode (cathode) of the light emitting diode Del is connected to a low level voltage Vss.

In the subpixel SP, when the switching transistor Tsw is turned on according to the gate voltage Vsc, the data voltage Vda is applied to the gate electrode of the driving transistor Tdr. When the driving transistor Tdr is turned on according to the data voltage Vda, a current corresponding to the data voltage Vda is supplied to the light emitting diode Del due to the high level voltage Vdd and the low level voltage Vss, and the light emitting diode Del emits a light corresponding to the data voltage Vda. The storage capacitor Cst stores the data voltage Vda to maintain a voltage of the gate electrode of the driving transistor Tdr for one frame.

Although the subpixel SP has a 2T1C structure including two transistors and one capacitor in the first embodiment of FIG. 2, the subpixel SP may have one of 4T1C, 5T1C, 3T2C, 4T2C, 5T2C, 6T2C, 7T1C, 7T2C, 8T1C and 8T2C structures in another embodiment.

In the display device 110, first and second electrodes of a vertical light emitting diode chip may be disposed horizontally.

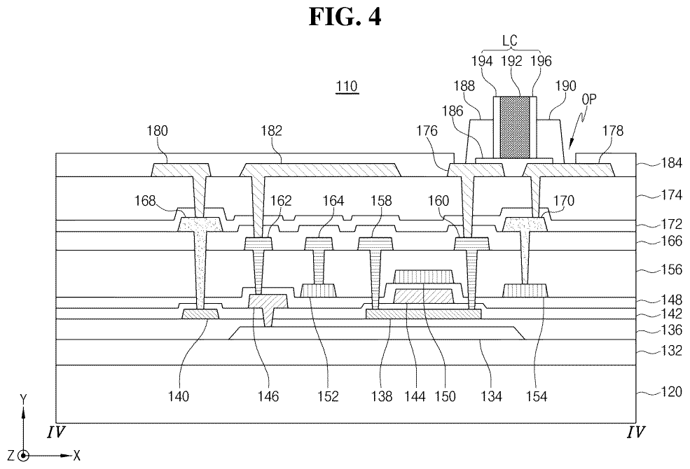

FIG. 3 is a plan view showing a rigid part of a display device according to a first embodiment of the present disclosure, and FIG. 4 is a cross-sectional view taken along a line IV-IV of FIG. 3.

In FIGS. 3 and 4, a first buffer layer 132 is disposed on the entire substrate 120 of the rigid part, and a light shielding layer 134 is disposed on the first buffer layer 132.

The substrate 120 has a relatively high elastic coefficient. For example, the substrate 120 may include a polyimide (PI) resin or an epoxy resin.

The first buffer layer 132 blocks permeation of an external moisture or an external oxygen. For example, the first buffer layer 132 may have a single layer or a multiple layer of an inorganic insulating material such as silicon nitride (SiNx), silicon oxide (SiOx) and silicon oxynitride (SiON).

The light shielding layer 134 blocks an incident light from an exterior. For example, the light shielding layer 134 may have a single layer or a multiple layer of a metallic material, and the metallic material may include at least one of aluminum (Al), copper (Cu), molybdenum (Mo), titanium (Ti), chromium (Cr), nickel (Ni), tungsten (W) and an alloy thereof.

A second buffer layer 136 is disposed on the light shielding layer 134 over the entire substrate 120. A first semiconductor layer 138 is disposed on the second buffer layer 136 corresponding to the light shielding layer 134, and a second semiconductor layer 140 is disposed on the second buffer layer 136 spaced apart from the first semiconductor layer 138.

The second buffer layer 136 blocks external moisture or external oxygen. For example, the second buffer layer 136 may have a single layer or multiple layers of an inorganic insulating material such as silicon nitride (SiNx), silicon oxide (SiOx) and silicon oxynitride (SiON).

Each of the first and second semiconductor layers 138 and 140 has a channel region at a central portion thereof and source and drain regions at both sides of the channel region. For example, each of the first and second semiconductor layers 138 and 140 may include polycrystalline silicon.

A gate insulating layer 142 is disposed on the first and second semiconductor layers 138 and 140 over the entire substrate 120. A gate electrode 144 is disposed on the gate insulating layer 142 corresponding to the first semiconductor layer 138, and a first connecting electrode 146 is disposed on the gate insulating layer 142 spaced apart from the gate electrode 144 and corresponding to the light shielding layer 134.

For example, the gate insulating layer 142 may have a single layer or multiple layers of an inorganic insulating material such as silicon nitride (SiNx), silicon oxide (SiOx) and/or silicon oxynitride (SiON).

For example, each of the gate electrode 144 and the first connecting electrode 146 may have a single layer or a multiple layer of a metallic material, and the metallic material may include at least one of aluminum (Al), copper (Cu), molybdenum (Mo), titanium (Ti), chromium (Cr), nickel (Ni), tungsten (W) and/or an alloy thereof.

The first connecting electrode 146 may contact the light shielding layer 134 through a contact hole in the gate insulating layer 142 and the second buffer layer 136.

A first interlayer insulating layer 148 is disposed on the gate electrode 144 and the first connecting electrode 146 over the entire substrate 120. An auxiliary electrode 150 is disposed on the first interlayer insulating layer 148 corresponding to the gate electrode 144, and an auxiliary line 152 and a pad electrode 154 are disposed on the first interlayer insulating layer 148 spaced apart from the auxiliary electrode 150.

For example, the first interlayer insulating layer 148 may have a single layer or a multiple layer of an inorganic insulating material such as silicon nitride (SiNx), silicon oxide (SiOx) or silicon oxynitride (SiON).

For example, each of the auxiliary electrode 150, the auxiliary line 152 and the pad electrode 154 may have a single layer or a multiple layer of a metallic material, and the metallic material may include at least one of aluminum (Al), copper (Cu), molybdenum (Mo), titanium (Ti), chromium (Cr), nickel (Ni), tungsten (W) and/or an alloy thereof.

The auxiliary line 152 may overlap the light shielding layer 134 and may be spaced apart from the gate electrode 144, the first and second semiconductor layers 138 and 140 and the first connecting electrode 146. The pad electrode 154 may be spaced apart from the light shielding layer 134.

A second interlayer insulating layer 156 is disposed on the auxiliary electrode 150, the auxiliary line 152 and the pad electrode 154 over the entire substrate 120, and source and drain electrodes 158 and 160 are disposed on the second interlayer insulating layer 156 corresponding to the first semiconductor layer 138. A second connecting electrode 162 is disposed on the second interlayer insulating layer 156 corresponding to the first connecting electrode 146, and a power line 164 is disposed on the second interlayer insulating layer 156 corresponding to the auxiliary line 152.

For example, second interlayer insulating layer 156 may have a single layer or a multiple layer of an inorganic insulating material such as silicon nitride (SiNx), silicon oxide (SiOx) and silicon oxynitride (SiON).

The source and drain electrodes 158 and 160 may contact the source and drain regions, respectively, of the first semiconductor layer 138 through a contact hole in the second interlayer insulating layer 156, the first interlayer insulating layer 148 and the gate insulating layer 142.

The first semiconductor layer 138, the gate electrode 144, the source electrode 158 and the drain electrode 160 may constitute the driving transistor Tdr.

The second connecting electrode 162 may contact the first connecting electrode 146 through a contact hole in the second interlayer insulating layer 156 and the first interlayer insulating layer 148, and the power line 164 may contact the auxiliary line 153 through a contact hole in the second interlayer insulating layer 156.

For example, the power line 164 may be a line supplying the low level voltage Vss, and the power line 164 or the auxiliary line 152 may be connected to the light shielding layer 134.

For example, each of the source electrode 158, the drain electrode 160, the second connecting electrode 162 and the power line 164 may have a single layer or a multiple layer of a metallic material, and the metallic material may include at least one of aluminum (Al), copper (Cu), molybdenum (Mo), titanium (Ti), chromium (Cr), nickel (Ni), tungsten (W) and an alloy thereof.

A third interlayer insulating layer 166 is disposed on the source electrode 158, the drain electrode 160, the second connecting electrode 162 and the power line 164 over the entire substrate 120, and a third connecting electrode 168 and an auxiliary pad 170 are disposed on the third interlayer insulating layer 166 corresponding to the second semiconductor layer 140 and the pad electrode 154, respectively.

For example, the third interlayer insulating layer 166 may have a single layer or a multiple layer of an inorganic insulating material such as silicon nitride (SiNx), silicon oxide (SiOx) and silicon oxynitride (SiON).

The third connecting electrode 168 may contact the second semiconductor layer 140 through a contact hole in the third interlayer insulating layer 166, the second interlayer insulating layer 156, the first interlayer insulating layer 148 and the gate insulating layer 142, and the auxiliary pad 170 may contact the pad electrode 154 through a contact hole in the third interlayer insulating layer 166 and the second interlayer insulating layer 156.

For example, each of the third connecting electrode 168 and the auxiliary pad 170 may have a single layer or a multiple layer of a metallic material, and the metallic material may include at least one of aluminum (Al), copper (Cu), molybdenum (Mo), titanium (Ti), chromium (Cr), nickel (Ni), tungsten (W) and/or an alloy thereof.

A passivation layer 172 and a first planarizing layer 174 are sequentially disposed on the third connecting electrode 168 and the auxiliary pad 170 over the entire substrate 120, and first, second, third and fourth electrodes 176, 178, 180 and 182 spaced apart from each other are disposed on the passivation layer 172.

For example, the passivation layer 172 may have a single layer or a multiple layer of an inorganic insulating material such as silicon nitride (SiNx), silicon oxide (SiOx) and silicon oxynitride (SiON).

The first planarizing layer 174 mitigates a step difference due to lower layers. For example, the first planarizing layer 174 may include an organic insulating material such as photosensitive acrylic polymer (e.g., photo acryl).

The first electrode 176 may contact the drain electrode 160 through a contact hole in the first planarizing layer 174, the passivation layer 172 and the third interlayer insulating layer 166, and the second electrode 178 may contact the auxiliary pad 170 through a contact hole in the first planarizing layer 174 and the passivation layer 172. The third electrode 180 may contact the third connecting electrode 168 through a contact hole in the first planarizing layer 174 and the passivation layer 172, and the fourth electrode 182 may contact the second connecting electrode 162 through a contact hole in the first planarizing layer 174, the passivation layer 172 and the third interlayer insulating layer 166.

For example, the first and second electrodes 176 and 178 may correspond to one subpixel SP in the substrate 120, and the third and fourth electrodes 180 and 182 may correspond to another subpixel SP in the substrate 120.

The first, second, third and fourth electrodes 176, 178, 180 and 182 may include copper (Cu).

A second planarizing layer 184 is disposed on the first, second, third and fourth electrodes 176, 178, 180 and 182 over the entire substrate 120.

The second planarizing layer 184 mitigates a step difference due to lower layers. For example, the second planarizing layer 184 may include an organic insulating material such as photosensitive acrylic polymer (e.g., photo acryl).

The second planarizing layer 184 has an opening OP exposing the first and second electrodes 176 and 178, and an adhesive layer 186 is disposed between the first and second electrodes 176 and 178 exposed through the opening OP of the second planarizing layer 184.

For example, the adhesive layer 186 may include one of an acrylic organic material, a urethane organic material and/or a silicone organic material.

A light emitting diode chip LC is disposed on the adhesive layer 186. A first connecting layer 188 is disposed between an anode 194 of the light emitting diode chip LC and the first electrode 176, and a second connecting layer 190 is disposed between a cathode 196 of the light emitting diode chip LC and the second electrode 178.

The light emitting diode chip LC includes a junction layer 192 and the anode 194 and the cathode 196 at both sides of the junction layer 192. The light emitting diode chip LC has a vertical type where the anode 194 and the cathode 196 are disposed at opposite sides, respectively.

For example, the junction layer 192 may include a negative type gallium nitride (n-GaN) layer, a multi quantum well (MQW) and a positive type gallium nitride (p-GaN) layer.

The light emitting diode chip LC may be disposed such that one side surface of the junction layer 192, the anode 194 and the cathode 196 contact a top portion of the adhesive layer 186.

The anode 194 of the light emitting diode chip LC is connected to the first electrode 176 through the first connecting layer 188, and the cathode 196 of the light emitting diode chip LC is connected to the second electrode 178 through the second connecting layer 190.

For example, each of the first and second connecting layers 188 and 190 may have a single layer or a multiple layer of a metallic material, and the metallic material may include at least one of aluminum (Al), copper (Cu), molybdenum (Mo), titanium (Ti), chromium (Cr), nickel (Ni), tungsten (W) and an alloy thereof.

The light emitting diode chip LC may have a shape such that a length between the anode 194 and the cathode 196 is smaller than at least one of lengths of first and second sides of each of the anode 194 and the cathode 196.

For example, when lengths of first and second sides of each of the anode 194 and the cathode 196 of the light emitting diode chip LC are a and b, respectively, and a length between the anode 194 and the cathode 196 of the light emitting diode chip LC is c, the light emitting diode chip LC may have a shape satisfying one of relations of (c<a), (c<b) and (c<a, b).

A method of fabricating the display device 110 will be illustrated with reference to drawings.

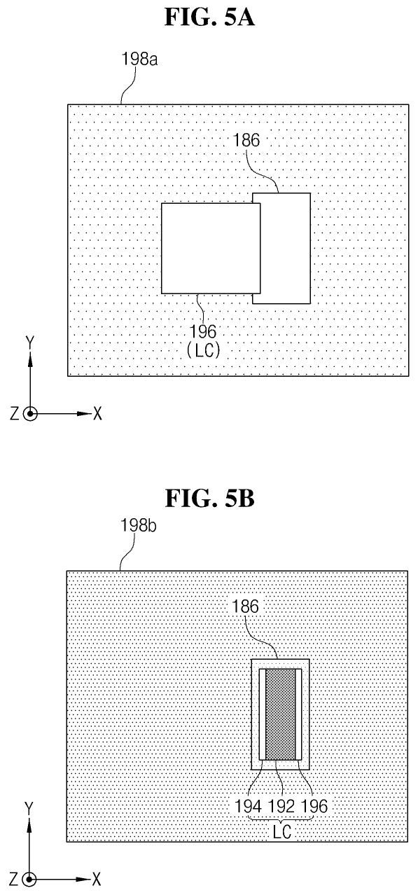

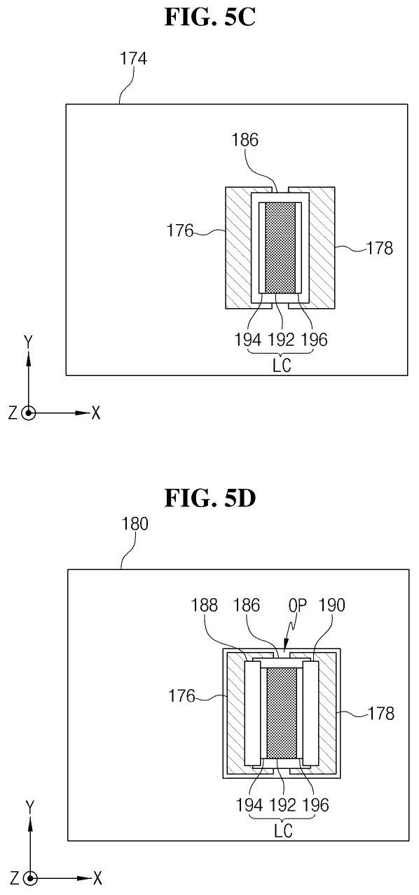

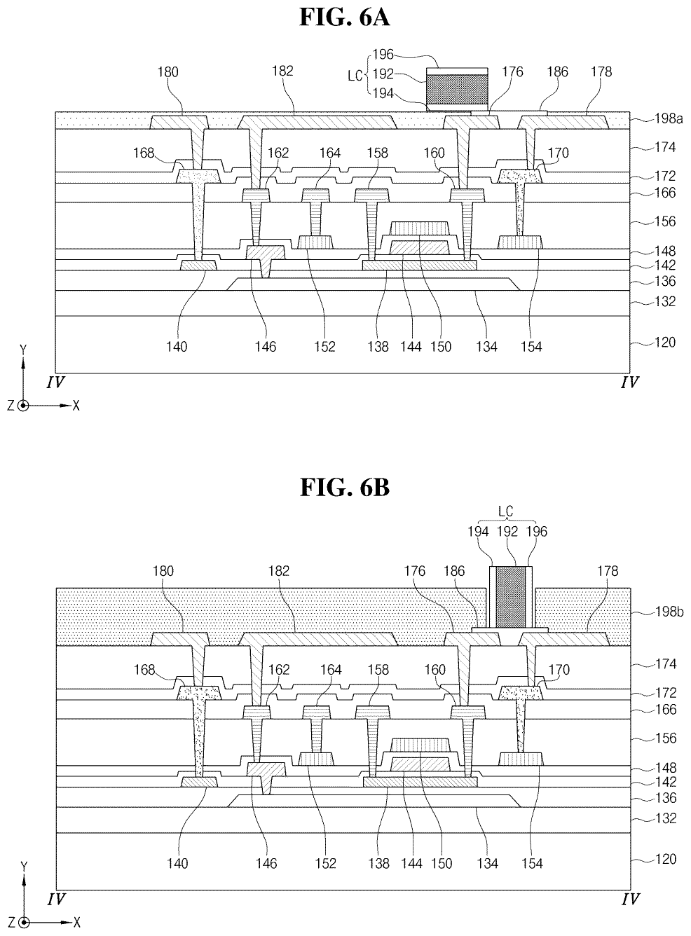

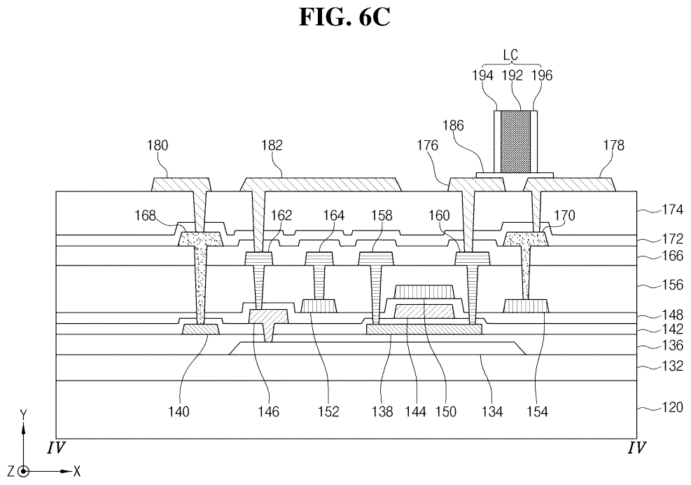

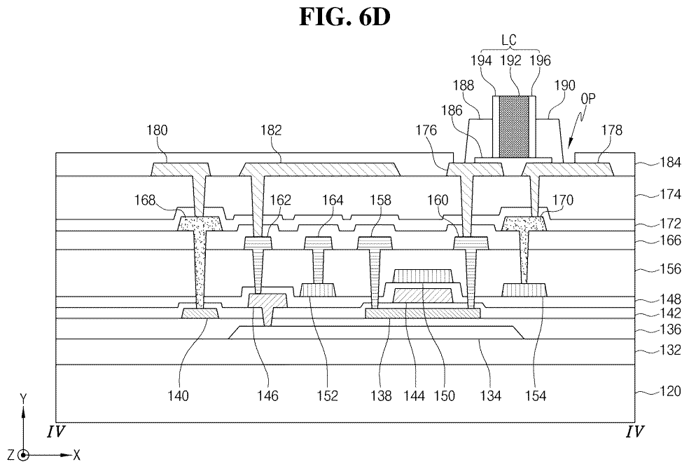

FIGS. 5A to 5D are plan views showing a method of fabricating a display device according to a first embodiment of the present disclosure, and FIGS. 6A to 6D are cross-sectional views showing a method of fabricating a display device according to a first embodiment of the present disclosure.

In FIGS. 5A and 6A, the first buffer layer 132 is formed on the entire substrate 120. After a metallic material layer is formed on the first buffer layer 132, the light shielding layer 134 is formed through a photolithographic process of patterning the metallic material layer including a photoresist deposition step, an exposure step and an etching step.

The second buffer layer 136 is formed on the light shielding layer 134 over the entire substrate 120. After a semiconductor material layer is formed on the second buffer layer 136, the first semiconductor layer 138 corresponding to the light shielding layer 134 and the second semiconductor layer 140 spaced apart from the first semiconductor layer 138 are formed through a photolithographic process of patterning the semiconductor material layer.

The gate insulating layer 142 is formed on the first and second semiconductor layers 138 and 140 over the entire substrate 120. After a metallic material is formed on the gate insulating layer 142, the gate electrode 144 corresponding to the first semiconductor layer 138 and the first connecting electrode 146 spaced apart from the gate electrode 144 and corresponding to the light shielding layer 134 are formed through a photolithographic process of patterning the metallic material layer.

The first interlayer insulating layer 148 is formed on the gate electrode 144 and the first connecting electrode 146 over the entire substrate 120. After a metallic material layer is formed on the first interlayer insulating layer 148, the auxiliary electrode 150 corresponding to the gate electrode 144 and the auxiliary line 152 and the pad electrode 154 spaced apart from the auxiliary electrode 150 are formed through a photolithographic process of patterning the metallic material layer.

The second interlayer insulating layer 156 is formed on the auxiliary electrode 150, the auxiliary line 152 and the pad electrode 154 over the entire substrate 120. After a metallic material layer is formed on the second interlayer insulating layer 156, the source and drain electrodes 158 and the 160 corresponding to the first semiconductor layer 138, the second connecting electrode 162 corresponding to the first connecting electrode 146 and the power line 164 corresponding to the auxiliary line 152 are formed through a photolithographic process of patterning the metallic material layer.

The third interlayer insulating layer 166 is formed on the source electrode 158, the drain electrode 160, the second connecting electrode 162 and the power line 164 over the entire substrate 120. After a metallic material layer is formed on the third interlayer insulating layer 166, the third connecting electrode 168 and the auxiliary pad 170 corresponding to the second semiconductor layer 140 and the pad electrode 154, respectively, are formed through a photolithographic process of patterning the metallic material layer.

The passivation layer 172 and the first planarizing layer 174 are sequentially formed on the third connecting electrode 168 and the auxiliary pad 170 over the entire substrate 120. After a metallic material layer is formed on the first planarizing layer 174, the first, second, third and fourth electrodes 176, 178, 180 and 182 spaced apart from each other are formed through a photolithographic process of patterning the metallic material layer.

The adhesive layer 186 is formed between the first and second electrodes 176 and 178, and a first expanding layer 198a exposing the adhesive layer 186 is formed on the first, second, third and fourth electrodes 176, 178, 180 and 182.

For example, the expanding layer 198a may include one of hydrogel, organogel and/or a foamed adhesive material.

A top surface of the adhesive layer 186 and a top surface of the first expanding layer 198a may constitute a flat surface.

The light emitting diode chip LC is disposed on a border portion of the adhesive layer 186 and the first expanding layer 198a.

For example, the light emitting diode chip LC may be disposed such that one of the anode 194 and the cathode 196 contacts the border portion of the adhesive layer 186 and the first expanding layer 198a and the other of the anode 194 and the cathode 196 faces upward.

A portion of the one of the anode 194 and the cathode 196 of the light emitting diode chip LC may contact the adhesive layer 186 and the other portion of the one of the anode 194 and the cathode 196 of the light emitting diode chip LC may contact the first expanding layer 198a.

In FIGS. 5B and 6B, the first expanding layer 198a is expanded by adding a heat to the first expanding layer 198a through a heat treatment step to form a second expanding layer 198b.

Since the first expanding layer 198a under the light emitting diode chip LC is expanded, a portion of the light emitting diode chip LC contacting the first expanding layer 198a rises upwardly and the other portion of the light emitting diode chip LC contacting the adhesive layer 186 remains in the adhesive layer 186.

As a result, the light emitting diode chip LC is disposed on the adhesive layer 186 such that the anode 194 and the cathode 196 are disposed horizontally.

The second expanding layer 198b is disposed to cover a portion of the adhesive layer 186 and expose the other portion of the adhesive layer 186. The light emitting diode chip LC is disposed such that one side surface of the junction layer 192, the anode 194 and the cathode 196 contact the adhesive layer 186 exposed through the second expanding layer 198b.

In FIGS. 5C and 6C, the first, second, third and fourth electrodes 176, 178, 180 and 182 and the first planarizing layer 174 are exposed by removing the second expanding layer 198b.

For example, the second expanding layer 198b may be removed through a rinsing step.

In FIGS. 5D and 6D, the second planarizing layer 184 is formed on the first, second, third and fourth electrodes 176, 178, 180 and 182 over the entire substrate 120.

The second planarizing layer 184 has the opening OP exposing the first and second electrodes 176 and 178, the adhesive layer 186 and the light emitting diode chip LC.

After a metallic material layer is formed on the second planarizing layer 184 and the light emitting diode chip LC, the first connecting layer 188 is formed between the anode 194 of the light emitting diode chip LC and the first electrode 176 and the second connecting layer 190 is formed between the cathode 196 of the light emitting diode LC and the second electrode 178 through a photolithographic process of patterning the metallic material layer.

The anode 194 of the light emitting diode chip LC is connected to the first electrode 176 through the first connecting layer 188, and the cathode 196 of the light emitting diode chip LC is connected to the second electrode 178 through the second connecting layer 190.

In the display device 110 according to a first embodiment of the present disclosure, the anode 194 and the cathode 196 of the vertical light emitting diode chip LC are disposed horizontally, and the anode 194 and the cathode 196 are connected to the first and second electrodes 176 and 178 through the first and second connecting layers 188 and 190, respectively. As a result, a fabrication process is simplified to obtain a fabrication optimization.

Further, since the anode 194 and the cathode 196 of the vertical light emitting diode chip LC having a relatively low cost are disposed horizontally, a thickness of the display device 110 is reduced and a fabrication cost of the display device 110 is reduced.

In another embodiment, the second expanding layer 196b may be used without removal.

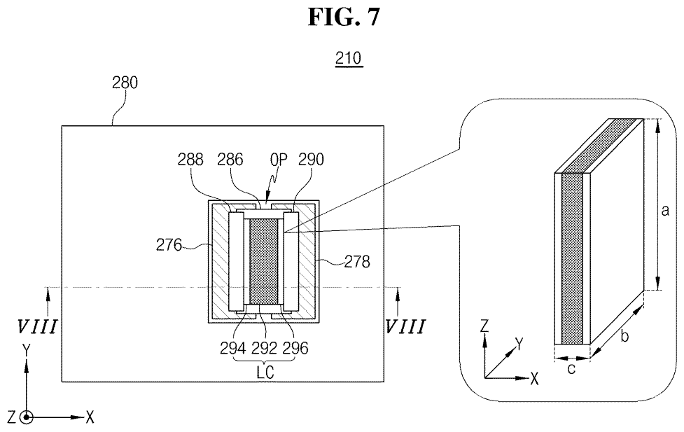

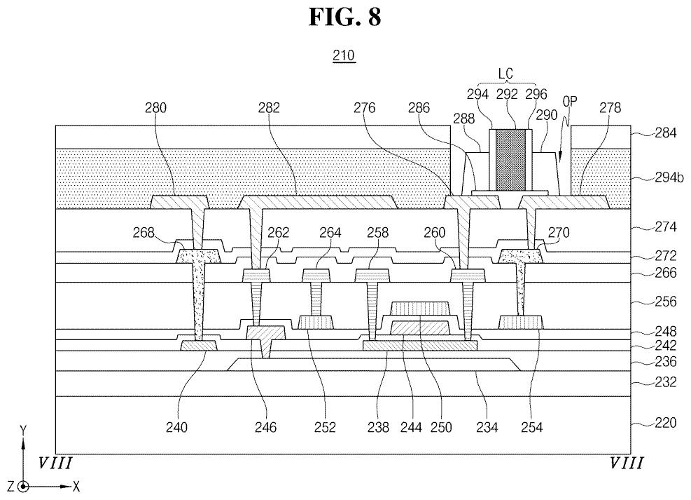

FIG. 7 is a plan view showing a rigid part of a display device according to a second embodiment of the present disclosure, and FIG. 8 is a cross-sectional view taken along a line VIII-VIII of FIG. 7. Illustrations on the same part as the first embodiment may be omitted.

In FIGS. 7 and 8, a first buffer layer 232 is disposed on an entire substrate 220 of a rigid part, and a light shielding layer 234 is disposed on the first buffer layer 232.

A second buffer layer 236 is disposed on the light shielding layer 234 over the entire substrate 220. A first semiconductor layer 238 is disposed on the second buffer layer 236 corresponding to the light shielding layer 234, and a second semiconductor layer 240 is disposed on the second buffer layer 236 spaced apart from the first semiconductor layer 238.

A gate insulating layer 242 is disposed on the first and second semiconductor layers 238 and 240 over the entire substrate 220. A gate electrode 244 is disposed on the gate insulating layer 242 corresponding to the first semiconductor layer 238, and a first connecting electrode 246 is disposed on the gate insulating layer 242 spaced apart from the gate electrode 244 and corresponding to the light shielding layer 234.

A first interlayer insulating layer 248 is disposed on the gate electrode 244 and the first connecting electrode 246 over the entire substrate 220. An auxiliary electrode 250 is disposed on the first interlayer insulating layer 248 corresponding to the gate electrode 244, and an auxiliary line 252 and a pad electrode 254 are disposed on the first interlayer insulating layer 248 spaced apart from the auxiliary electrode 250.

A second interlayer insulating layer 256 is disposed on the auxiliary electrode 250, the auxiliary line 252 and the pad electrode 254 over the entire substrate 220, and source and drain electrodes 258 and 260 are disposed on the second interlayer insulating layer 256 corresponding to the first semiconductor layer 238. A second connecting electrode 162 is disposed on the second interlayer insulating layer 156 corresponding to the first connecting electrode 146, and a power line 164 is disposed on the second interlayer insulating layer 156 corresponding to the auxiliary line 152.

A third interlayer insulating layer 266 is disposed on the source electrode 258, the drain electrode 260, the second connecting electrode 262 and the power line 264 over the entire substrate 220, and a third connecting electrode 268 and an auxiliary pad 270 are disposed on the third interlayer insulating layer 266 corresponding to the second semiconductor layer 240 and the pad electrode 254, respectively.

A passivation layer 272 and a first planarizing layer 274 are sequentially disposed on the third connecting electrode 268 and the auxiliary pad 270 over the entire substrate 220, and first, second, third and fourth electrodes 276, 278, 280 and 282 spaced apart from each other are disposed on the passivation layer 272.

A second planarizing layer 284 is disposed on the first, second, third and fourth electrodes 276, 278, 280 and 282 over the entire substrate 220, and an adhesive layer 286 is disposed between the first and second electrodes 276 and 278 exposed through an opening OP of the second planarizing layer 284.

A light emitting diode chip LC is disposed on the adhesive layer 286. A first connecting layer 288 is disposed between an anode 294 of the light emitting diode chip LC and the first electrode 276, and a second connecting layer 290 is disposed between a cathode 296 of the light emitting diode chip LC and the second electrode 278.

The light emitting diode chip LC may have a shape such that a length between the anode 294 and the cathode 296 is smaller than at least one of lengths of first and second sides of each of the anode 294 and the cathode 296.

A method of fabricating the display device 210 will be illustrated with reference to drawings.

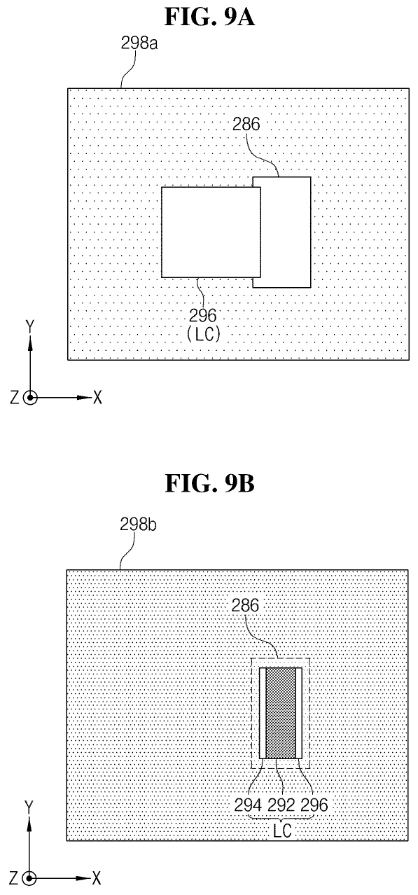

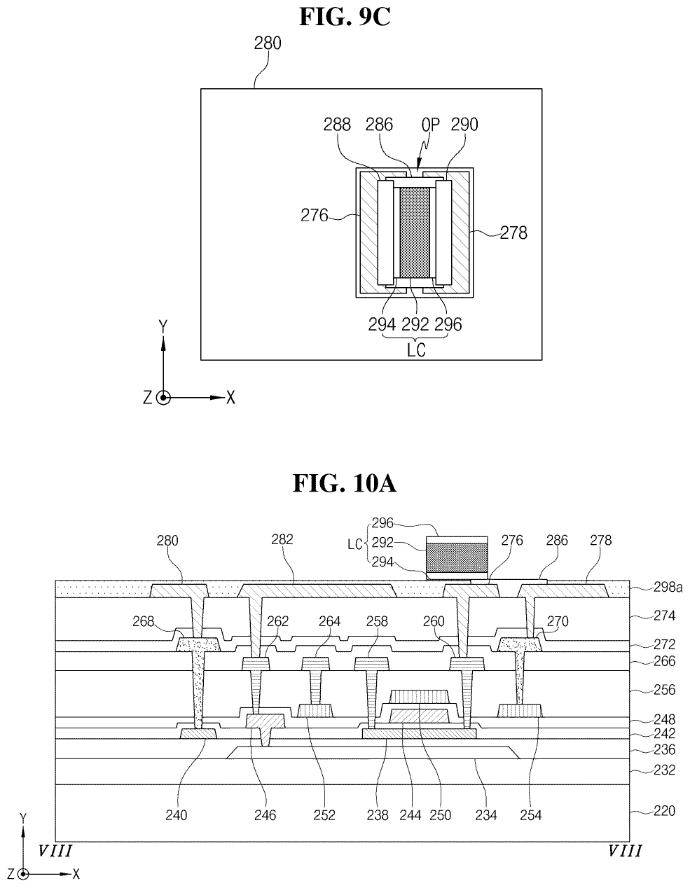

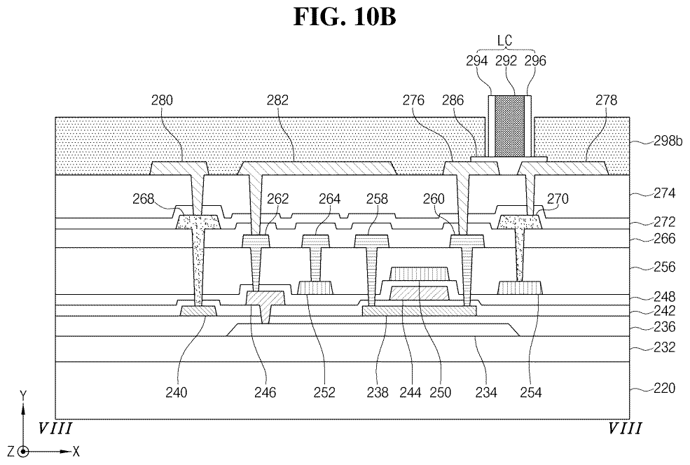

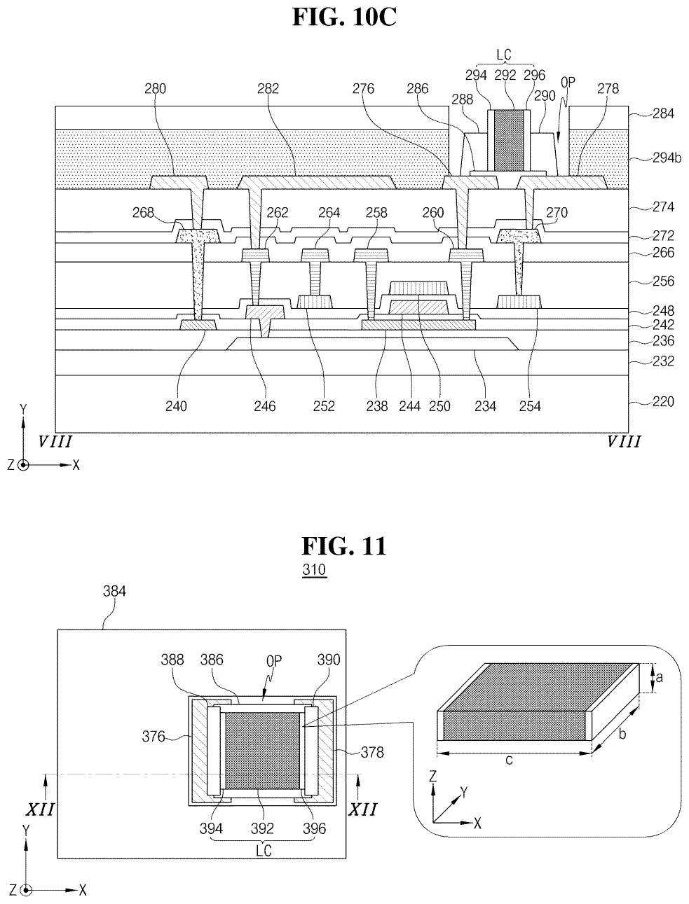

FIGS. 9A to 9C are plan views showing a method of fabricating a display device according to a second embodiment of the present disclosure, and FIGS. 10A to 10C are cross-sectional views showing a method of fabricating a display device according to a second embodiment of the present disclosure. Illustrations on the same part as the first embodiment may be omitted.

In FIGS. 9A and 10A, the first buffer layer 232 is formed on the entire substrate 220. After a metallic material layer is formed on the first buffer layer 232, the light shielding layer 234 is formed through a photolithographic process of patterning the metallic material layer including a photoresist deposition step, an exposure step and an etching step.

The second buffer layer 236 is formed on the light shielding layer 234 over the entire substrate 220. After a semiconductor material layer is formed on the second buffer layer 236, the first semiconductor layer 238 corresponding to the light shielding layer 234 and the second semiconductor layer 240 spaced apart from the first semiconductor layer 238 are formed through a photolithographic process of patterning the semiconductor material layer.

The gate insulating layer 242 is formed on the first and second semiconductor layers 238 and 240 over the entire substrate 220. After a metallic material is formed on the gate insulating layer 242, the gate electrode 244 corresponding to the first semiconductor layer 238 and the first connecting electrode 246 spaced apart from the gate electrode 244 and corresponding to the light shielding layer 234 are formed through a photolithographic process of patterning the metallic material layer.

The first interlayer insulating layer 248 is formed on the gate electrode 244 and the first connecting electrode 246 over the entire substrate 220. After a metallic material layer is formed on the first interlayer insulating layer 248, the auxiliary electrode 250 corresponding to the gate electrode 244 and the auxiliary line 252 and the pad electrode 254 spaced apart from the auxiliary electrode 250 are formed through a photolithographic process of patterning the metallic material layer.

The second interlayer insulating layer 256 is formed on the auxiliary electrode 250, the auxiliary line 252 and the pad electrode 254 over the entire substrate 220. After a metallic material layer is formed on the second interlayer insulating layer 256, the source and drain electrodes 258 and the 260 corresponding to the first semiconductor layer 238, the second connecting electrode 262 corresponding to the first connecting electrode 246 and the power line 264 corresponding to the auxiliary line 252 are formed through a photolithographic process of patterning the metallic material layer.

The third interlayer insulating layer 266 is formed on the source electrode 258, the drain electrode 260, the second connecting electrode 262 and the power line 264 over the entire substrate 220. After a metallic material layer is formed on the third interlayer insulating layer 266, the third connecting electrode 268 and the auxiliary pad 270 corresponding to the second semiconductor layer 240 and the pad electrode 254, respectively, are formed through a photolithographic process of patterning the metallic material layer.

The passivation layer 272 and the first planarizing layer 274 are sequentially formed on the third connecting electrode 268 and the auxiliary pad 270 over the entire substrate 220. After a metallic material layer is formed on the first planarizing layer 274, the first, second, third and fourth electrodes 276, 278, 280 and 282 spaced apart from each other are formed through a photolithographic process of patterning the metallic material layer.

The adhesive layer 286 is formed between the first and second electrodes 276 and 278, and a first expanding layer 298a exposing the adhesive layer 286 is formed on the first, second, third and fourth electrodes 276, 278, 280 and 282.

For example, the expanding layer 298a may include one of hydrogel, organogel and/or a foamed adhesive material.

A top surface of the adhesive layer 286 and a top surface of the first expanding layer 298a may constitute a flat surface.

The light emitting diode chip LC is disposed on a border portion of the adhesive layer 286 and the first expanding layer 298a.

For example, the light emitting diode chip LC may be disposed such that one of the anode 294 and the cathode 296 contacts the border portion of the adhesive layer 286 and the first expanding layer 298a and the other of the anode 294 and the cathode 296 faces upward.

A portion of the one of the anode 294 and the cathode 296 of the light emitting diode chip LC may contact the adhesive layer 286 and the other portion of the one of the anode 294 and the cathode 296 of the light emitting diode chip LC may contact the first expanding layer 298a.

In FIGS. 9B and 10B, the first expanding layer 298a is expanded by adding a heat to the first expanding layer 298a through a heat treatment step to form a second expanding layer 298b.

Since the first expanding layer 298a under the light emitting diode chip LC is expanded, a portion of the light emitting diode chip LC contacting the first expanding layer 298a rises upwardly and the other portion of the light emitting diode chip LC contacting the adhesive layer 286 remains in the adhesive layer 286.

As a result, the light emitting diode chip LC is disposed on the adhesive layer 286 such that the anode 294 and the cathode 296 are disposed horizontally.

The second expanding layer 298b is disposed to cover a portion of the adhesive layer 286 and expose the other portion of the adhesive layer 286. The light emitting diode chip LC is disposed such that one side surface of the junction layer 292, the anode 294 and the cathode 296 contact the adhesive layer 286 exposed through the second expanding layer 298b.

In FIGS. 9C and 10C, the second planarizing layer 284 is formed on the second expanding layer 298b over the entire substrate 220.

The second planarizing layer 284 and the second expanding layer 298b have the opening OP exposing the first and second electrodes 276 and 278, the adhesive layer 286 and the light emitting diode LC.

After a metallic material layer is formed on the second planarizing layer 284 and the light emitting diode chip LC, the first connecting layer 288 is formed between the anode 294 of the light emitting diode chip LC and the first electrode 276 and the second connecting layer 290 is formed between the cathode 296 of the light emitting diode LC and the second electrode 278 through a photolithographic process of patterning the metallic material layer.

The anode 294 of the light emitting diode chip LC is connected to the first electrode 276 through the first connecting layer 288, and the cathode 296 of the light emitting diode chip LC is connected to the second electrode 278 through the second connecting layer 290.

In the display device 210 according to a second embodiment of the present disclosure, the anode 294 and the cathode 296 of the vertical light emitting diode chip LC are disposed horizontally, and the anode 294 and the cathode 296 are connected to the first and second electrodes 276 and 278 through the first and second connecting layers 288 and 290, respectively, by one process. As a result, a fabrication process is simplified to obtain a fabrication optimization.

Further, since the anode 294 and the cathode 296 of the vertical light emitting diode chip LC having a relatively low cost are disposed horizontally, a thickness of the display device 210 is reduced and a fabrication cost of the display device 210 is reduced.

In another embodiment, the anode and the cathode of the vertical light emitting diode chip may be disposed horizontally using a roller.

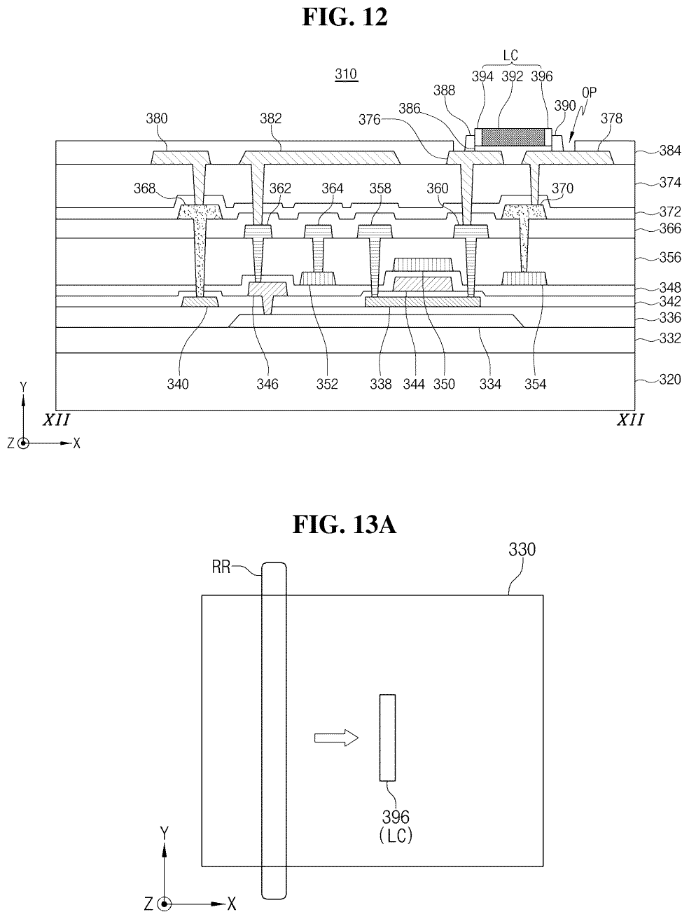

FIG. 11 is a plan view showing a rigid part of a display device according to a third embodiment of the present disclosure, and FIG. 12 is a cross-sectional view taken along a line XII-XII of FIG. 11. Illustrations on the same part as the first and second embodiments may be omitted.

In FIGS. 11 and 12, a first buffer layer 332 is disposed on an entire substrate 320 of a rigid part, and a light shielding layer 334 is disposed on the first buffer layer 332.

A second buffer layer 336 is disposed on the light shielding layer 334 over the entire substrate 320. A first semiconductor layer 338 is disposed on the second buffer layer 336 corresponding to the light shielding layer 334, and a second semiconductor layer 340 is disposed on the second buffer layer 336 spaced apart from the first semiconductor layer 338.

A gate insulating layer 342 is disposed on the first and second semiconductor layers 338 and 340 over the entire substrate 320. A gate electrode 344 is disposed on the gate insulating layer 342 corresponding to the first semiconductor layer 338, and a first connecting electrode 346 is disposed on the gate insulating layer 342 spaced apart from the gate electrode 344 and corresponding to the light shielding layer 334.

A first interlayer insulating layer 348 is disposed on the gate electrode 344 and the first connecting electrode 346 over the entire substrate 320. An auxiliary electrode 350 is disposed on the first interlayer insulating layer 348 corresponding to the gate electrode 344, and an auxiliary line 352 and a pad electrode 354 are disposed on the first interlayer insulating layer 348 spaced apart from the auxiliary electrode 350.

A second interlayer insulating layer 356 is disposed on the auxiliary electrode 350, the auxiliary line 352 and the pad electrode 354 over the entire substrate 320, and source and drain electrodes 358 and 360 are disposed on the second interlayer insulating layer 356 corresponding to the first semiconductor layer 338. A second connecting electrode 362 is disposed on the second interlayer insulating layer 356 corresponding to the first connecting electrode 346, and a power line 364 is disposed on the second interlayer insulating layer 356 corresponding to the auxiliary line 352.

A third interlayer insulating layer 366 is disposed on the source electrode 358, the drain electrode 360, the second connecting electrode 362 and the power line 364 over the entire substrate 320, and a third connecting electrode 368 and an auxiliary pad 370 are disposed on the third interlayer insulating layer 366 corresponding to the second semiconductor layer 340 and the pad electrode 354, respectively.

A passivation layer 372 and a first planarizing layer 374 are sequentially disposed on the third connecting electrode 368 and the auxiliary pad 370 over the entire substrate 320, and first, second, third and fourth electrodes 376, 378, 380 and 382 spaced apart from each other are disposed on the passivation layer 372.

A second planarizing layer 384 is disposed on the first, second, third and fourth electrodes 376, 378, 380 and 382 over the entire substrate 320, and an adhesive layer 386 is disposed between the first and second electrodes 376 and 378 exposed through an opening OP of the second planarizing layer 384.

A light emitting diode chip LC is disposed on the adhesive layer 386. A first connecting layer 388 is disposed between an anode 394 of the light emitting diode chip LC and the first electrode 376, and a second connecting layer 390 is disposed between a cathode 396 of the light emitting diode chip LC and the second electrode 378.

The light emitting diode chip LC may have a shape such that a length between the anode 394 and the cathode 396 is greater than at least one of lengths of first and second sides of each of the anode 394 and the cathode 396.

For example, when lengths of first and second sides of each of the anode 394 and the cathode 396 of the light emitting diode chip LC are a and b, respectively, and a length between the anode 394 and the cathode 396 of the light emitting diode chip LC is c, the light emitting diode chip LC may have a shape satisfying one of relations of (c>a), (c>b) and (c>a, b).

A method of fabricating the display device 310 will be illustrated with reference to drawings.

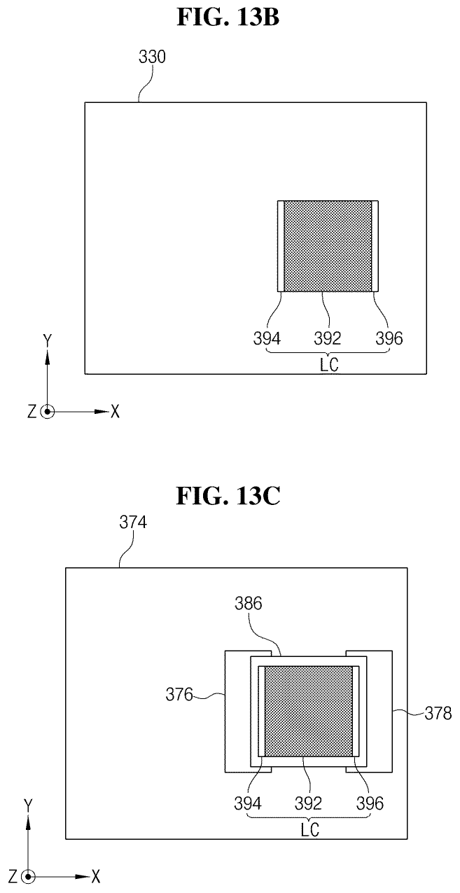

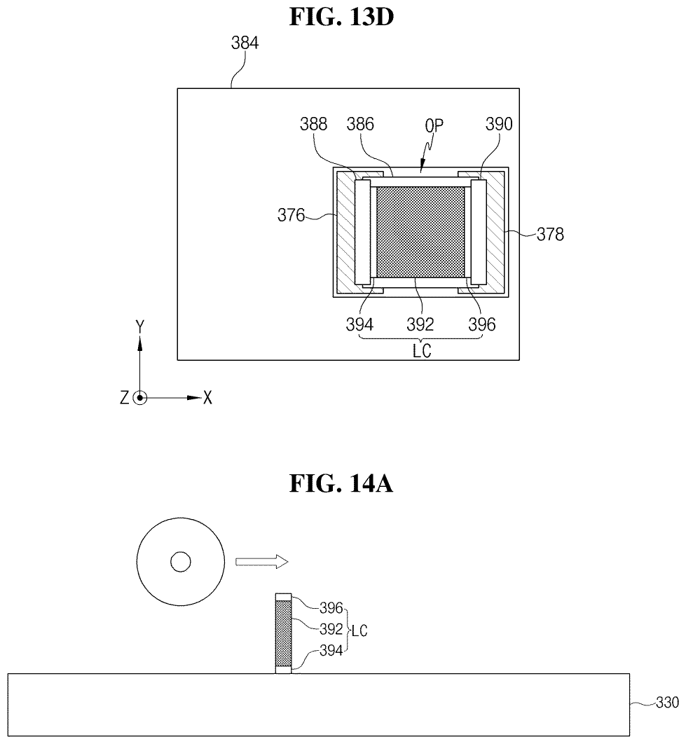

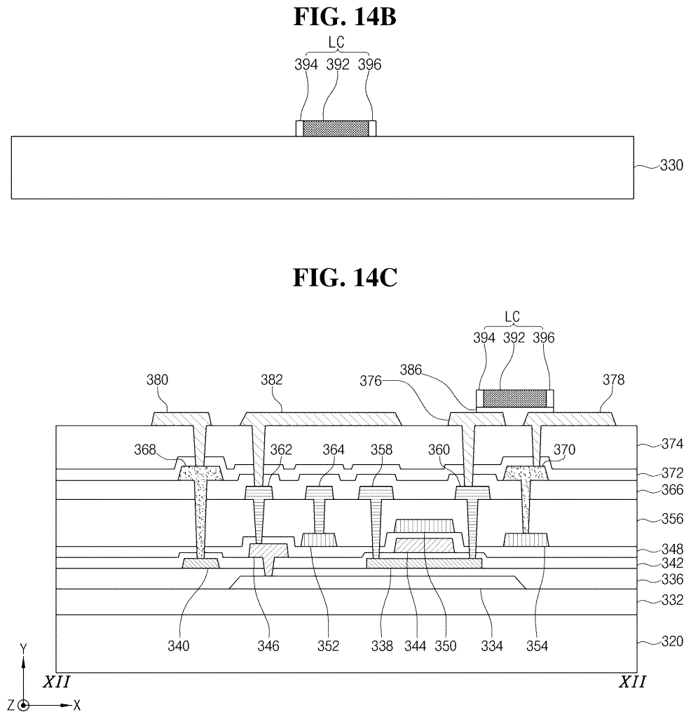

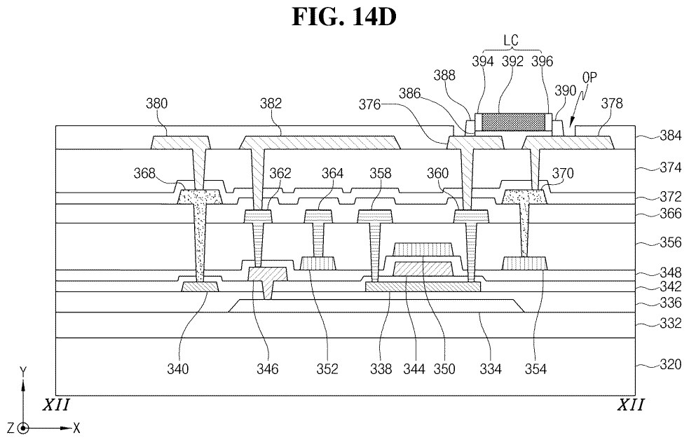

FIGS. 13A to 13D are plan views showing a method of fabricating a display device according to a third embodiment of the present disclosure, and FIGS. 14A to 14D are cross-sectional views showing a method of fabricating a display device according to a third embodiment of the present disclosure. Illustrations on the same part as the first and second embodiments may be omitted.

In FIGS. 13A and 14A, the light emitting diode chip LC is transferred onto a transfer substrate 330 from a mother substrate such as a wafer.

For example, the light emitting diode chip LC may be disposed such that one of the anode 394 and the cathode 396 contacts the transfer substrate 330 and the other of the anode 394 and the cathode 396 faces upward.

Next, the light emitting diode chip LC is pushed using a roller RR to be fallen.

For example, the roller RR may push an upper portion of the light emitting diode chip LC by sensing a gap distance between the roller RR and the transfer substrate 330 and by keeping the gate distance constant.

In FIGS. 13B and 14B, the light emitting diode chip LC is disposed such that one side surface of the light emitting diode chip LC contacts the transfer substrate 330.

For example, the light emitting diode chip LC may be disposed such that one side surface of the junction layer 392, the anode 394 and the cathode 396 of the light emitting diode chip LC contacts the transfer substrate 330 and the other side surface of the junction layer 392, the anode 394 and the cathode 396 of the light emitting diode chip LC face upward.

In FIGS. 13C and 14C, the first buffer layer 332 is formed on the entire substrate 320. After a metallic material layer is formed on the first buffer layer 332, the light shielding layer 334 is formed through a photolithographic process of patterning the metallic material layer including a photoresist deposition step, an exposure step and an etching step.

The second buffer layer 336 is formed on the light shielding layer 334 over the entire substrate 320. After a semiconductor material layer is formed on the second buffer layer 336, the first semiconductor layer 338 corresponding to the light shielding layer 334 and the second semiconductor layer 340 spaced apart from the first semiconductor layer 338 are formed through a photolithographic process of patterning the semiconductor material layer.

The gate insulating layer 342 is formed on the first and second semiconductor layers 338 and 340 over the entire substrate 320. After a metallic material is formed on the gate insulating layer 342, the gate electrode 344 corresponding to the first semiconductor layer 338 and the first connecting electrode 346 spaced apart from the gate electrode 344 and corresponding to the light shielding layer 334 are formed through a photolithographic process of patterning the metallic material layer.

The first interlayer insulating layer 348 is formed on the gate electrode 344 and the first connecting electrode 346 over the entire substrate 320. After a metallic material layer is formed on the first interlayer insulating layer 348, the auxiliary electrode 350 corresponding to the gate electrode 344 and the auxiliary line 352 and the pad electrode 354 spaced apart from the auxiliary electrode 350 are formed through a photolithographic process of patterning the metallic material layer.

The second interlayer insulating layer 356 is formed on the auxiliary electrode 350, the auxiliary line 352 and the pad electrode 354 over the entire substrate 320. After a metallic material layer is formed on the second interlayer insulating layer 356, the source and drain electrodes 358 and the 360 corresponding to the first semiconductor layer 338, the second connecting electrode 362 corresponding to the first connecting electrode 346 and the power line 364 corresponding to the auxiliary line 352 are formed through a photolithographic process of patterning the metallic material layer.

The third interlayer insulating layer 366 is formed on the source electrode 358, the drain electrode 360, the second connecting electrode 362 and the power line 364 over the entire substrate 320. After a metallic material layer is formed on the third interlayer insulating layer 366, the third connecting electrode 368 and the auxiliary pad 370 corresponding to the second semiconductor layer 340 and the pad electrode 354, respectively, are formed through a photolithographic process of patterning the metallic material layer.

The passivation layer 372 and the first planarizing layer 374 are sequentially formed on the third connecting electrode 368 and the auxiliary pad 370 over the entire substrate 320. After a metallic material layer is formed on the first planarizing layer 374, the first, second, third and fourth electrodes 376, 378, 380 and 382 spaced apart from each other are formed through a photolithographic process of patterning the metallic material layer.

The adhesive layer 386 is formed between the first and second electrodes 376 and 378, and the light emitting diode chip LC of the transfer substrate 330 is transferred onto the adhesive layer 386.

For example, the light emitting diode chip LC may be disposed such that the other side surface of the junction layer 392, the anode 394 and the cathode 396 of the light emitting diode chip LC contact the substrate 330 and the one side surface of the junction layer 392, the anode 394 and the cathode 396 of the light emitting diode chip LC face upward.

In FIGS. 13D and 14D, the second planarizing layer 384 is formed on the first, second, third and fourth electrodes 376, 378, 380 and 382 over the entire substrate 320.

The second planarizing layer 384 has the opening OP exposing the first and second electrodes 376 and 378, the adhesive layer 386 and the light emitting diode LC.

After a metallic material layer is formed on the second planarizing layer 384 and the light emitting diode chip LC, the first connecting layer 388 is formed between the anode 394 of the light emitting diode chip LC and the first electrode 376 and the second connecting layer 390 is formed between the cathode 396 of the light emitting diode LC and the second electrode 378 through a photolithographic process of patterning the metallic material layer.

The anode 394 of the light emitting diode chip LC is connected to the first electrode 376 through the first connecting layer 388, and the cathode 396 of the light emitting diode chip LC is connected to the second electrode 378 through the second connecting layer 390.

In the display device 310 according to a third embodiment of the present disclosure, the anode 394 and the cathode 396 of the vertical light emitting diode chip LC are disposed horizontally, and the anode 394 and the cathode 396 are connected to the first and second electrodes 376 and 378 through the first and second connecting layers 388 and 390, respectively, by one process. As a result, a fabrication process is simplified to obtain a fabrication optimization.

Further, since the anode 394 and the cathode 396 of the vertical light emitting diode chip LC having a relatively low cost are disposed horizontally, a thickness of the display device 310 is reduced and a fabrication cost of the display device 310 is reduced.

It will be apparent to those skilled in the art that various modifications and variations can be made in the present disclosure without departing from the scope of the disclosure. Thus, it is intended that the present disclosure cover the modifications and variations of this disclosure provided they come within the scope of the appended claims.

What is claimed is:

1. A display device, comprising:
a substrate;
a thin film transistor on the substrate;
a first electrode connected to the thin film transistor and a second electrode spaced apart from the first electrode;
an adhesive layer between the first electrode and the second electrode;
a light emitting diode chip on the adhesive layer, the light emitting diode chip including a junction layer, an anode, and a cathode, the anode and the cathode at both sides of the junction layer;
a first connecting layer between the first electrode and the anode; and
a second connecting layer between the second electrode and the cathode,
wherein the anode and the cathode are disposed horizontally.

2. The display device of claim 1, wherein one side surface of the junction layer, the anode and the cathode are in contact with the adhesive layer.

3. The display device of claim 1, wherein the anode is connected to the first electrode through the first connecting layer, and the cathode is connected to the second electrode through the second connecting layer.

4. The display device of claim 1, further comprising:
a planarizing layer on the first electrode and the second electrode, the planarizing layer having an opening that exposes the first electrode, the second electrode, the adhesive layer and the light emitting diode chip.

5. The display device of claim 4, further comprising:
an expanding layer between the first electrode and the second electrode and the planarizing layer.

6. The display device of claim 5, wherein the expanding layer includes one of hydrogel, organogel or a foamed adhesive material.

7. A method of fabricating a display device, comprising:
forming a thin film transistor on a substrate;
forming a first electrode connected to the thin film transistor and a second electrode spaced apart from the first electrode;
forming an adhesive layer between the first electrode and the second electrode;
forming a first expanding layer that exposes the adhesive layer on the first electrode and the second electrode;
disposing a light emitting diode chip on the adhesive layer and the first expanding layer, the light emitting diode chip including a junction layer, an anode and a cathode, the anode and the cathode on both sides of the junction layer;
forming a second expanding layer by applying heat to the first expanding layer; and
forming a first connecting layer between the first electrode and the anode and a second connecting layer between the second electrode and the cathode,
wherein the anode and the cathode are disposed horizontally.

8. The method of claim 7, further comprising:
forming a planarizing layer on the first electrode and the second electrode, the planarizing layer having an opening that exposes the first electrode, the second electrode, the adhesive layer and the light emitting diode chip.

9. The method of claim 7, further comprising:
removing the second expanding layer.

10. The method of claim 7, wherein a length between the anode and the cathode is smaller than at least one of lengths of a first side or a second side of each of the anode and the cathode.

11. A method of fabricating a display device, comprising:
transferring a light emitting diode chip onto a transfer substrate such that one of an anode and a cathode of the light emitting diode chip contacts the transfer substrate;
pushing the light emitting diode chip with a roller;
transferring the light emitting diode chip of the transfer substrate onto an adhesive layer of a substrate, the substrate including:
a thin film transistor,
a first electrode connected to the thin film transistor,
a second electrode spaced apart from the first electrode, and
the adhesive layer between the first electrode and the second electrode; and
forming a first connecting layer between the first electrode and the anode and a second connecting layer between the second electrode and the cathode,
wherein the anode and the cathode are disposed horizontally.

12. The method of claim 11, further comprising:
forming a planarizing layer on the first electrode and the second electrode, the planarizing layer having an opening that exposes the first electrode, the second electrode, the adhesive layer and the light emitting diode chip.

13. The method of claim 11, wherein a length between the anode and the cathode is greater than at least one of lengths of a first side or a second side of each of the anode and the cathode.
